(19) United States
(12) Patent Application Publication
(10) Pub. No.: US 2026/0016524 A1
(43) Pub. Date: Jan. 15, 2026

(54) INSPECTION APPARATUS

(71) Applicant: KABUSHIKI KAISHA NIHON MICRONICS, TOKYO (JP)

(72) Inventors: KATSUO YASUTA, TOKYO (JP); TAKESHI SAITO, TOKYO (JP); TOMOKAZU SAITO, TOKYO (JP); JUNICHIRO SAITO, TOKYO (JP)

(73) Assignee: KABUSHIKI KAISHA NIHON MICRONICS, TOKYO (JP)

(21) Appl. No.: 19/265,240

(22) Filed: Jul. 10, 2025

(30) Foreign Application Priority Data
Jul. 12, 2024 (JP) 2024-112777

(51) Int. Cl. G01R 31/26; G01R 1/067

(52) U.S. Cl. CPC G01R 31/2607; G01R 1/067

(57) ABSTRACT

To make it possible to accurately measure a surface temperature of a device under test during testing. An inspection apparatus according to the present disclosure configured to test a device under test by contacting an electrode terminal of the device under test with a conductive contact to electrically connect between a tester and the device under test, includes: a device-under-test support unit that supports the device under test; an infrared-light receiving unit that receives infrared rays radiated from the device under test, at least the device under test being as an object to be temperature-measured; and a temperature measuring device having a temperature conversion function of converting the infrared rays from the infrared-light receiving unit into a temperature of the object to be temperature-measured, wherein the device-under-test support unit has a black body at a peripheral edge region or in a vicinity of the peripheral edge of the device-under-test support unit.

### CROSS-REFERENCE TO RELATED APPLICATIONS

The present application claims priority under 35 U.S.C. § 119 to Japanese Patent Application No. 2024-112777 filed on Jul. 12, 2024. The contents of this application are incorporated herein by reference in their entirety.

### TECHNICAL FIELD

The present disclosure relates to an inspection apparatus, and can be applied, for example, to a semiconductor inspection apparatus (hereafter also referred to as “inspection apparatus”) that tests electrical characteristics of a semiconductor integrated circuit (hereafter also referred to as “semiconductor device”) formed on a semiconductor wafer (hereafter also referred to as simply “wafer”).

### BACKGROUND ART

During a manufacturing process of semiconductor devices formed on a wafer, since it is necessary to test whether electrical characteristics of the semiconductor devices satisfy predetermined values, a semiconductor inspection apparatus in which a probe card is incorporated has been used for testing.

For example, a probe card having a plurality of probes is connected to a test head to connect the probes to terminals of semiconductor devices formed on a wafer. Then, a tester provides test signals through the probes to each semiconductor device on the wafer and acquires response signals from each semiconductor device to test electrical characteristics of each semiconductor device.

In recent years, there has been a demand to test whether the electrical characteristics of the semiconductor devices satisfy predetermined values even under predetermined temperature environments, and it is therefore necessary to accurately and precisely measure a surface temperature of the wafers (semiconductor device) under test.

Conventionally, there has been a temperature measuring device described in Patent Literature 1 for measuring a surface temperature of wafers, which measures an amount of infrared radiation radiated from the wafers using an infrared sensor (refer to Patent Literature 1).

In this case, it is necessary to calibrate the temperature measuring device using emissivity of a black body. In a conventional method for calibrating the temperature measuring device, for example, the temperature measuring device is removed from a prober and calibrated using a radiation temperature of a blackbody furnace or the like as a reference. Moreover, a wafer-shaped black body is placed on a chuck of the prober, and changes in a measurement value of the amount of infrared radiation are monitored to verify whether the measurement value is within a certain range. When the measurement value falls outside the certain range, the accuracy is verified again using the wafer-shaped black body, and recalibration is performed if necessary. In this manner, the temperature of the wafer is measured in a non-contact manner using the infrared sensor.

### CITATION LIST

### Patent Literature

Patent Literature 1: Japanese Patent Application Laid-Open No. 2001-056253

### SUMMARY OF INVENTION

### Technical Problem

However, when the surface temperature of a wafer (semiconductor device) under test is measured using a non-contact temperature sensor, the semiconductor device generates heat when an operating current is applied to the semiconductor device, and then the heat is transferred to an electrical signal probe in contact with a terminal of the semiconductor device, causing the temperature of the semiconductor device to change and to be difficult to stabilize.

Therefore, when attempting to accurately measure the surface temperature of a wafer under test using such a conventional temperature measuring device, the following problems arise.

Infrared rays generated from the surface of the semiconductor device are transmitted to the temperature measuring device through an optical path formed with an optical fiber, a body tube, a lens, etc., but transmittance may become deteriorated due to a fitting condition, deterioration, etc. of optical path members, which may affect the measurement accuracy.

Moreover, when a temperature of the optical path itself increases, infrared rays are generated from the optical path, and there is a risk of being affected by the infrared rays.

Further, there is a problem that the amount of infrared radiation from a wafer changes depending on the color, roughness, and other states of a surface of the wafer as an object to be measured.

Furthermore, there is a problem that when a distance from a light receiving unit of an optical fiber (such as a tip of the fiber) to the semiconductor device, which is an object to be measured, changes, an incident angle of infrared rays to the light receiving unit may change, and thus the amount of entering light also changes.

In view of the above-described problems, the present disclosure aims to provide an inspection apparatus capable of accurately measuring a surface temperature of a wafer during testing.

### Solution to Problem

In order to solve such problems, an inspection apparatus according to present disclosure configured to test a device under test by contacting an electrode terminal of the device under test with a conductive contact to electrically connect between a tester and the device under test, the inspection apparatus includes: (1) a device-under-test support unit configured to support the device under test; (2) an infrared-light receiving unit configured to receive infrared rays radiated from the device under test, at least the device under test being as an object to be temperature-measured; and (3) a temperature measuring device having a temperature conversion function of converting the infrared rays from the infrared-light receiving unit into a temperature of the object to be temperature-measured, wherein (4) the device-under-test support unit has a black body at a peripheral edge region or in a vicinity of the peripheral edge of the device-under-test support unit.

### Advantageous Effects of Invention

According to the present disclosure, it is possible to improve efficiency of a calibration work for a non-contact thermometer which is transported in the inspection apparatus and measures a surface temperature of the device under test during testing or a surface temperature of a placement table on which the device under test is placed.

### BRIEF DESCRIPTION OF DRAWINGS

FIG. 1 is an overall configuration diagram illustrating an overall configuration of an inspection apparatus according to a first embodiment.

FIG. 2 is a top view diagram illustrating a configuration of a device-under-test placement table according to the first embodiment in a plan view.

FIG. 3 is a flow chart illustrating an operation of a calibration process of a temperature measuring device in the inspection apparatus according to the first embodiment (Example 1).

FIG. 4 is an explanatory diagram for describing a movement of a position of a black body in the first embodiment.

FIG. 5 is a flow chart illustrating an operation of the calibration process of the temperature measuring device in the inspection apparatus according to the first embodiment (Example 2).

FIG. 6 is an overall configuration diagram illustrating an overall configuration of the inspection apparatus according to a second embodiment.

FIG. 7 is an explanatory diagram for describing a distance measurement performed by a length measuring device according to the second embodiment.

FIG. 8 is a flow chart illustrating an operation of a calibration process of the temperature measuring device in the inspection apparatus according to the second embodiment.

FIG. 9 is a diagram illustrating a relationship between a distance between a wafer surface and an infrared-light receiving unit and a corrected temperature in the second embodiment.

### DESCRIPTION OF EMBODIMENTS

### (A) First Embodiment

Hereinafter, a first embodiment of an inspection apparatus according to the present disclosure will be described in detail with reference to drawings.

In the description of the following drawings to be explained, the identical reference sign is attached to the equivalent part. However, it should be noted that the drawings are schematic and, for example, the ratio of the thickness of each component element differs from an actual thing. Moreover, the part from which the relation and ratio of a mutual size differ also in mutually drawings is included. Moreover, the embodiments described hereinafter merely exemplify the device and method for materializing the technical ideas of the present disclosure; and the material, shape, structure, placement, etc. of each component are not limited to those described in the embodiments.

### (A-1) Configuration of First Embodiment

### (A-1-1) Overall Configuration

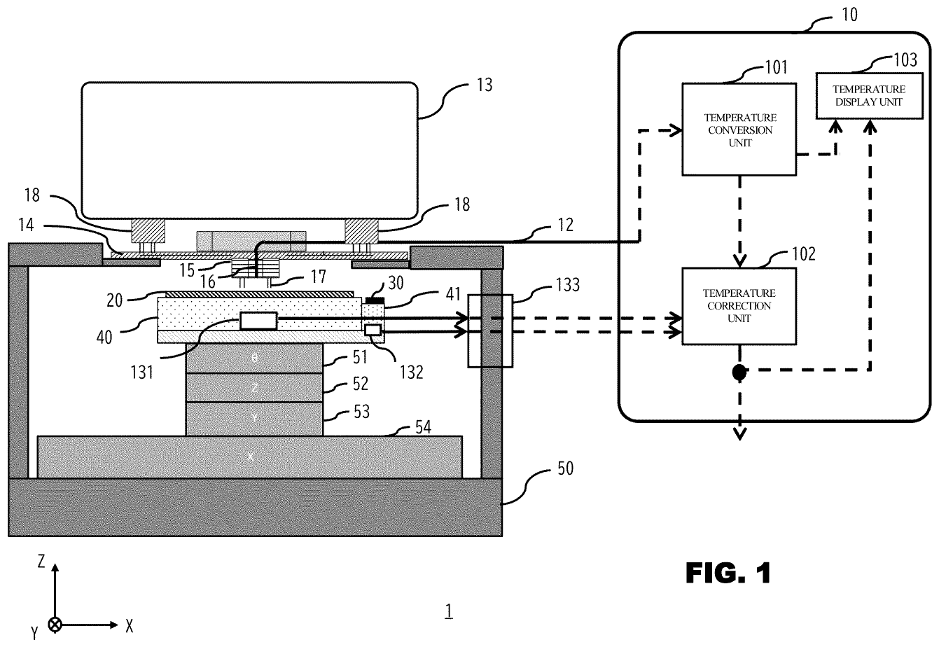

FIG. 1 is an overall configuration diagram illustrating an overall configuration of an inspection apparatus according to a first embodiment.

In FIG. 1, an inspection apparatus 1 according to the first embodiment includes a temperature measuring device 10, a prober 50, and a test head 13.

The prober 50 includes a chuck 40 on which a wafer 20 is placed and having a temperature adjustment function of adjusting a temperature of the wafer 20 to a high temperature or a low temperature, and a θ-axis stage 51, a Z-axis stage 52, a Y-axis stage 53 and an X-axis stage 54.

The inspection apparatus 1 tests electrical characteristics of each semiconductor device (hereinafter, also referred to as “device under test”) formed on the wafer 20. In the inspection apparatus 1, a probe card 14 is electrically connected to a second surface (e.g., a lower surface) of the test head 13 through an electrical connection unit 18.

During testing, an electrode terminal of a semiconductor device is electrically contacted to each probe 17 of the probe card 14. Then, the inspection apparatus 1 provides electrical signals from a tester to each semiconductor device on the wafer 20 through the probes and acquires signals in response from each semiconductor device. Thus, the tester tests characteristics of the semiconductor devices.

The temperature measuring device 10 is connected to an optical fiber 12, which is connected to an infrared-light receiving unit 16. The infrared-light receiving unit 16 receives infrared rays radiated from an object to be temperature-measured (hereinafter also simply referred to as “object to be measured”), and the temperature measuring device 10 acquires the infrared rays radiated from the object to be measured through the optical fiber 12. The temperature measuring device 10 converts an amount of infrared radiation received from the infrared-light receiving unit 16 into temperature and measures a surface temperature of the object to be measured. Thus, the surface temperature of the object to be measured can be measured in a non-contact manner.

Moreover, the temperature measuring device 10 appropriately measures a surface temperature of a black body 30 placed on a first surface (e.g., an upper surface) of the chuck 40 periodically or as necessary and corrects the temperature measured by the temperature measuring device 10.

The temperature measuring device 10 includes a temperature conversion unit 101, a temperature correction unit 102, and a temperature display unit 103 as functional components.

The temperature conversion unit 101 acquires the infrared rays received by the infrared-light receiving unit 16 through the optical fiber 12 and converts the amount of infrared radiation from the object to be measured into the temperature.

The temperature correction unit 102 uses the black body 30 disposed at a peripheral edge region or near a peripheral edge of the chuck 40 as an object to be measured, switches the temperature of the chuck 40 to a temperature thereof required for measurement, and converts the amount of infrared radiation from the black body 30 acquired from the infrared-light receiving unit 16 at each measured temperature into the temperature. Moreover, the temperature correction unit 102 prepares a correction table in advance on the basis of the amount of infrared radiation and the temperature of the black body 30.

Then, the temperature correction unit 102 measures the temperature of the black body 30 periodically or as necessary on the basis of the amount of infrared radiation of the black body 30 received by the infrared-light receiving unit 16. The temperature correction unit 102 corrects a measurement result of the temperature measuring device 10 with reference to the correction table prepared in advance and the temperature on the basis of the amount of infrared radiation of the black body 30. This makes it possible to periodically calibrate the temperature measuring device 10 and to detect abnormalities in the infrared-light receiving unit 16, the temperature measuring device 10, etc.

The temperature display unit 103 displays the temperature derived by the temperature conversion unit 101 and the temperature corrected by the temperature correction unit 102. For example, a display unit, such as a liquid crystal display can be applied to the temperature display unit 103.

The temperature measuring device 10 has a function of receiving the amount of infrared radiation from the infrared-light receiving unit 16, converting the received amount of infrared radiation into the temperature, and then displaying the converted temperature or converting the converted temperature into an electrical signal and outputting the electrical signal to another device.

The test head 13 on the second surface (e.g., lower surface) side is connected to the probe card 14 through the electrical connection unit 18. The test head 13 is connected to a tester, which is not illustrated, and exchanges an electrical signal between the tester and the probe card 14. Thus, the electrical characteristics of the semiconductor device on the wafer 20 can be tested.

The electrical connection unit 18 is an attachment unit that attaches the probe card 14 to the test head 13 and electrically connects the test head 13 and the probe card 14 to each other.

The probe card 14 brings an electrode terminal of the semiconductor device formed on the wafer 20 in contact with the probe 17, and provides the electrical signal to the semiconductor device through the probe 17, and replies a response signal from the semiconductor device through the probe 17. The probe card 14 is an example of an electrical connection device that electrically connects between the tester and the semiconductor device on the wafer 20. The probe card 14 is provided with a probe assembly 15 having a plurality of probes 17 on a second surface (e.g., a lower surface) side thereof.

The probe assembly 15 is an assembly including a plurality of probes 17 and is provided on the second surface (e.g., the lower surface) side of the probe card 14.

The probe 17 is a conductive contact that forms an electrical path with the electrode terminal of the semiconductor device. The type of probe 17 is not particularly limited, and, for example, a cantilever type probe and a vertical type probe can be applied.

It is to be noted that this embodiment illustrates a case of the conductive contact that forms the electrical path between the probe 17 and the electrode terminal of the semiconductor device, but when the semiconductor device is an optical semiconductor, the probe 17 may include, in addition to the conductive contact, an optical probe (e.g., an optical fiber) that exchanges an optical signal between the optical input/output units of the optical semiconductor and the probe 17.

The chuck 40 fixes the wafer 20 on the first surface (also referred to as “chuck top” or “chuck stage”) of the chuck 40 and moves in X, Y, Z, and θ-axis directions. The chuck 40 is also provided with one or a plurality of black bodies 30 on the upper surface of the chuck 40. An installation method of the black body 30 will be described later.

The chuck 40 includes a chuck temperature sensor (also referred to as “first temperature sensor”) 131 that detects temperature of the chuck 40, a blackbody-placement-unit temperature sensor (also referred to as “second temperature sensor”) 132 that detects temperature of a blackbody placement unit 41 on which the black body 30 is placed, and a temperature signal exchange unit 133 which is an interface with the temperature measuring device 10.

The temperature signal exchange unit 133 transmits a chuck temperature signal from the chuck temperature sensor 131 and a blackbody-placement-unit temperature signal from the blackbody-placement-unit temperature sensor 132 to the temperature measuring device 10.

The θ-axis stage 51, the Z-axis stage 52, the Y-axis stage 53, and the X-axis stage 54 are movement drive mechanisms that move the chuck 40.

### (A-1-2) Detailed Configuration of Chuck 40

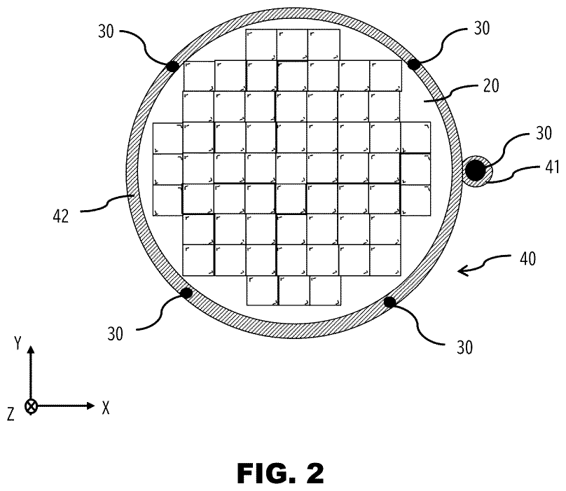

FIG. 2 is a top view diagram illustrating a configuration of the chuck 40 according to the first embodiment in a plan view.

As illustrated in FIG. 2, a shape of a wafer placement surface (an upper surface shape: i.e., a shape of chuck top) of the chuck 40 is approximately circular, and a size of the chuck 40 is slightly larger than a size of the wafer 20.

On a peripheral edge 42 of the wafer placement surface of the chuck 40, a black body 30 having a clearly predetermined relationship between temperature and an amount of infrared radiation is disposed.

The example in FIG. 2 illustrates a case in which a total of five black bodies 30 are provided, including four black bodies 30 placed on the peripheral edge 42 of the wafer placement surface of the chuck 40 and one black body 30 placed on the blackbody placement unit 41 provided at the peripheral edge 42. The four black bodies 30 are arranged on the peripheral edge 42 of the chuck 40 at equal intervals from one another.

The number of black bodies 30 arranged is not limited to this example, and one black body 30 may be disposed on the chuck 40, or two or more black bodies 30 may be disposed. The black body 30 is used as a reference for the amount of infrared radiation. Moreover, there is no particular limitation as long as it is possible to move the black body 30 to a position of the infrared-light receiving unit 16 when calibrating the temperature measuring device. Furthermore, a plurality of blackbody placement units 41 may be provided, and the black body 30 may be placed on each of the blackbody placement units 41.

The black body 30 is a thermal radiator in which there is a clearly known relationship between the temperature and the amount of infrared radiation in advance. For example, a seal-shaped black body (black body seal), a body painted with black body paint, or various other types may be applied to the black body 30.

When measurement accuracy of the temperature measuring device 10 is confirmed, when an abnormality in the measurement accuracy occurs, or when an abnormality in the measurement of the infrared sensor occurs, the temperature correction unit 102 converts the amount of infrared radiation radiated from the black body 30 into temperature and creates a correction table on the basis of a result thereof. The correction table is then referenced and used to correct the temperature signal output value of the temperature measuring device 10.

In other words, the amount of infrared radiation of the black body 30 can be measured during testing or periodically, the temperature can be derived from the amount of infrared radiation, and the temperature signal output value of the temperature measuring device 10 can be calibrated in the light of the temperature and the correction table.

Since the black body 30 is arranged on the wafer placement surface of the chuck 40, and thus the black body 30 can be moved to the position of the infrared-light receiving unit 16 and measured even during testing, the temperature signal output value of the temperature measuring device 10 can be calibrated without replacing the wafer 20.

It is to be noted that the black body 30 does not need to be an ideal perfect black body, and anything that can be regarded as a black body can be used.

### (A-2) Operation of First Embodiment

### (A-2-1) First Calibration Method

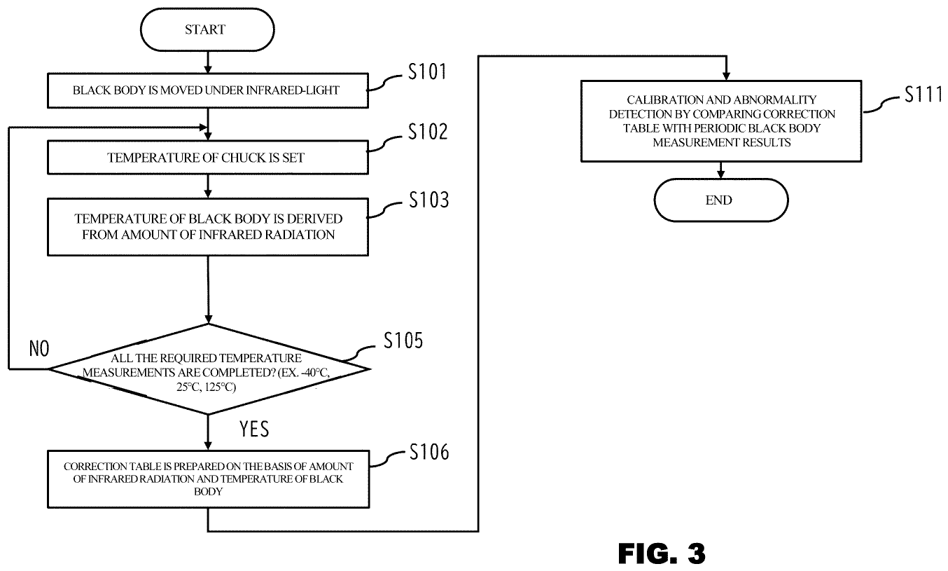

FIG. 3 is a flow chart illustrating an operation of a calibration process of the temperature measuring device 10 in the inspection apparatus 1 according to the first embodiment (Example 1).

An example of a periodical calibration performed by the temperature measuring device 10, for example, as an optical fiber type non-contact thermometer will be described here. It is to be noted that the order of the calibration process is not limited to the example illustrated in FIG. 3.

### [Step S101]

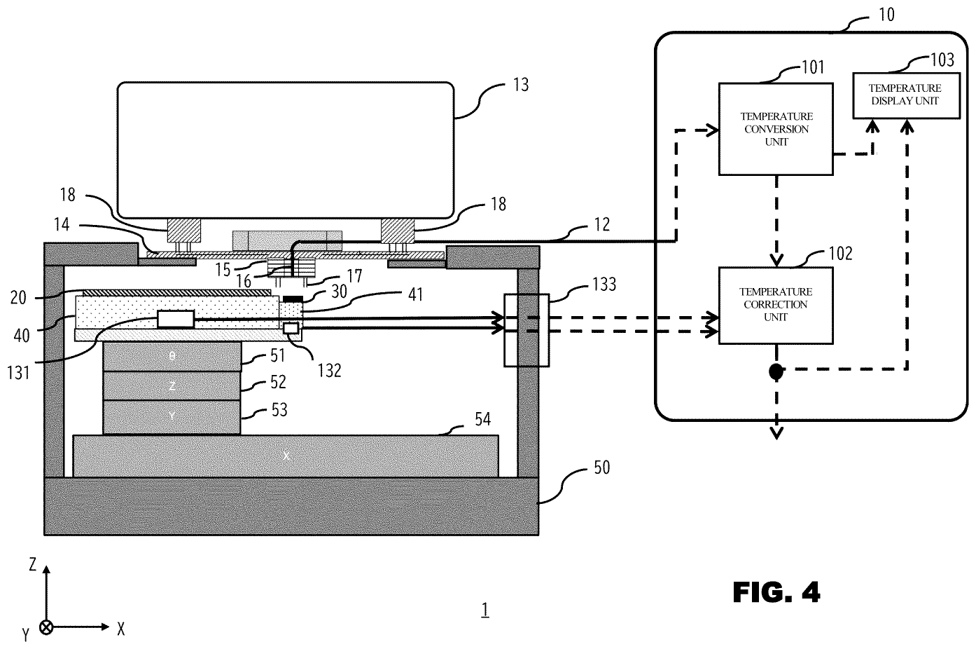

First, the θ-axis stage 51, the Z-axis stage 52, the Y-axis stage 53, and the X-axis stage 54 as a movement drive mechanism are driven so that the movement drive mechanism moves the peripheral edge region of the wafer placement surface of the chuck 40 and the black body 30 arranged in the vicinity of the peripheral edge to a position of the infrared-light receiving unit 16 as illustrated in FIG. 4 (Step S101).

### [Step S102]

Next, the temperature of the chuck 40 is set as a temperature required for the measurement (Step S102). For example, in the present embodiment, the temperature is set to “−40° C.”, “25° C.”, and “125° C.”.

### [Step S103]

When the temperature of the chuck 40 reaches the set temperature, the infrared-light receiving unit 16 receives infrared rays radiated from the black body 30 and transmits the infrared rays to the temperature measuring device 10 through the optical fiber 12. The temperature measuring device 10 converts the amount of infrared radiation from the black body 30 into temperature on the basis of the infrared rays from the infrared-light receiving unit 16 (Step S103).

### [Step S105]

Next, it is determined whether or not measurements have been completed at all temperatures required for the measurements (e.g., −40° C., 25° C., and 125° C.) (Step S105).

If the measurements are completed (YES in Step S105), the process proceeds to Step S106, and if the measurements are not completed (NO in Step S105), the process returns to Step S102, where the set temperature of the chuck 40 is changed and the process is continued.

### [Step S106]

A correction table (hereinafter, also referred to as “first correction table”) is prepared on the basis of the amount of infrared radiation from the black body 30 and the derived temperature (Step S106).

For example, when there is a preliminary relationship table prepared based on the relationship between the temperature and the amount of infrared radiation of the black body 30 in advance, the correction table is prepared by comparing between the preliminary relationship table and the measurement result obtained in Steps S102, S103, and S105.

### [Step S111]

The temperature measuring device 10 compares the correction table with the measurement results of the amount of infrared radiation from the black body 30 measured periodically and detects the temporal change of the infrared sensor and the change of the amount of infrared radiation from the wafer on the basis of the comparison results (Step S111).

### (A-2-2) Second Calibration Method

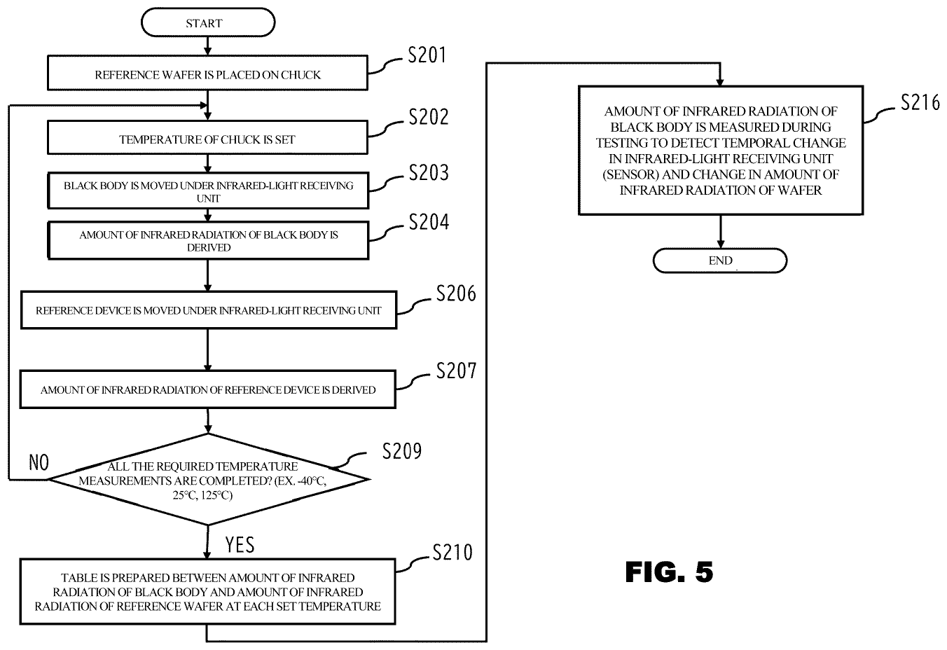

FIG. 5 is a flow chart illustrating an operation of the calibration process of the temperature measuring device 10 in the inspection apparatus 1 according to the first embodiment (Example 2).

An example of a calibration of a value obtained by converting, for example, an amount of infrared radiation corresponding to a surface temperature of the semiconductor device on the wafer during testing received by the temperature measuring device 10, into a temperature will be described here. It is to be noted that the order of the calibration process is not limited to the example illustrated in FIG. 5.

It is to be noted that the second calibration method is intended to perform calibration without removing the wafer 20 to be measured from the chuck 40.

This means, for example, that when testing the electrical characteristics of a semiconductor device on a certain wafer 20, the calibration process is performed without replacing the wafer 20 and without removing the temperature measuring device 10 from the prober 50. Alternatively, for example, calibration using the amount of infrared radiation from the black body 30 may be performed between the end of testing of a certain wafer 20 and the time when the next wafer 20 is placed on the chuck 40.

### [Steps S201 and S202]

First, a reference wafer is placed on the chuck 40 (Step S201), and a temperature of the chuck 40 is set to a temperature required for measurement (Step S202).

For example, in this embodiment, the temperature is set to “−40° C.”, “25° C.”, and “125° C.”, but the temperature values are not limited to these examples, and the number of temperature setting values is not limited to three.

### [Step S203]

The θ-axis stage 51, the Z-axis stage 52, the Y-axis stage 53, and the X-axis stage 54 as a movement drive mechanism are driven so that the movement drive mechanism moves the black body 30 on the chuck 40 to a position of the infrared-light receiving unit 16 (Step S203).

### [Step S204]

The infrared-light receiving unit 16 receives infrared rays radiated from the black body 30 and provides the received infrared rays to the temperature measuring device 10. The temperature measuring device 10 converts the amount of infrared radiation from the black body 30 into temperature on the basis of the infrared rays from the infrared-light receiving unit 16 (Step S204).

### [Step S206]

Next, a certain semiconductor device formed on the reference wafer is used as a reference device, and the reference device is moved to the position of the infrared-light receiving unit 16 (step S206). The reference device is an arbitrary device (semiconductor device) on the reference wafer.

### [Step S207]

The infrared-light receiving unit 16 receives infrared rays radiated from the reference device and provides the received infrared rays to the temperature measuring device 10. The temperature measuring device 10 converts the amount of infrared radiation from the reference device into temperature on the basis of the infrared rays from the infrared-light receiving unit 16 (Step S207).

### [Step S209]

Next, it is determined whether or not measurements have been completed at all temperatures required for the measurements (e.g., −40° C., 25° C., and 125° C.) (Step S209).

If the measurements are completed (YES in Step S209), the process proceeds to Step S210, and if the measurements are not completed (NO in Step S209), the process returns to Step S202, where the set temperature of the chuck 40 is changed and the process is continued.

### [Step S210]

The temperature measuring device 10 prepares a correction table (hereinafter also referred to as “second correction table”) indicating a relationship between the amount of infrared radiation from the black body 30 and the temperature signal value and a relationship between the amount of infrared radiation from the reference device and the temperature signal value at each set temperature.

### [Step S216]

During the testing, any one black body 30 among the plurality of black bodies 30 is moved under the infrared-light receiving unit 16, and the infrared-light receiving unit 16 receives the infrared rays radiated from the black body 30 and transmits the received infrared rays to the temperature measuring device 10. Then, the temperature measuring device 10 converts the amount of infrared radiation from the black body 30 into the temperature. It is to be noted that during testing, the temperature of the black body 30 may be periodically measured.

The temporal change of the infrared-light receiving unit 16 as an infrared sensor and the change in the amount of infrared radiation from the wafer are detected using the correction table prepared in S210 and the amount of infrared radiation and the temperature of the black body 30 measured during testing (Step S216).

### (A-3) Advantageous Effects of First Embodiment

As described above, conventionally, when the non-contact thermometer is calibrated, the non-contact thermometer is removed from the prober or the black body wafer for calibration is used. In contrast, according to the first embodiment, by providing the black body on the chuck, it becomes possible to perform calibration by measuring the radiation amount from the black body during testing or periodically. As a result, the burden of complex processing can be reduced, and the wafer surface temperature can be measured.

Moreover, according to the first embodiment, the calibration can be performed even during testing of the wafer (semiconductor device), and therefore the wafer surface temperature can be measured accurately.

### (B) Second Embodiment

Next, a second embodiment of the inspection apparatus according to the present disclosure will be described in detail with reference to drawings.

### (B-1) Configuration of Second Embodiment

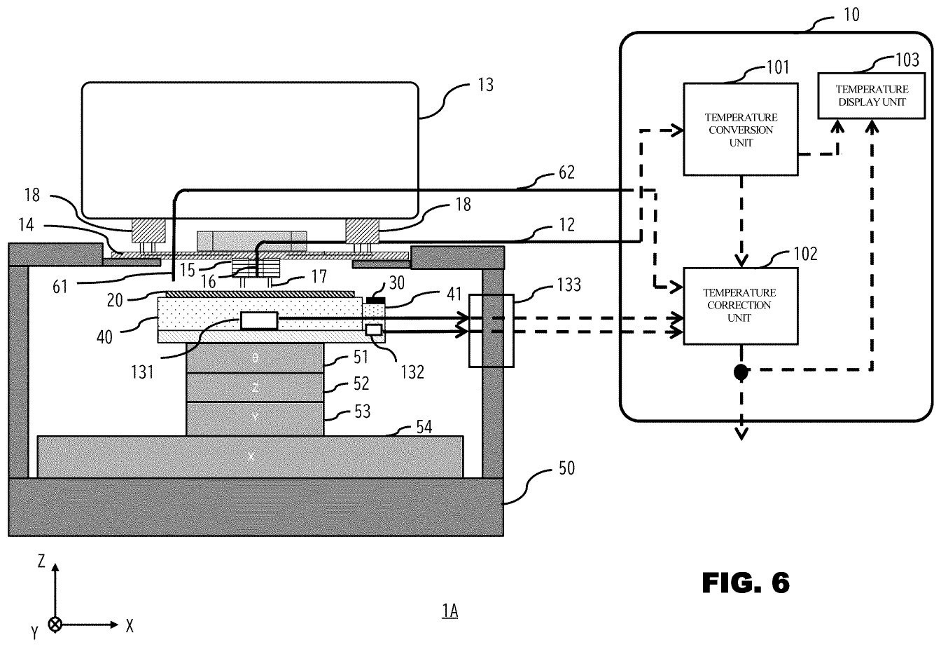

FIG. 6 is an overall configuration diagram illustrating an overall configuration of the inspection apparatus according to the second embodiment.

In FIG. 6, an inspection apparatus 1A according to the second embodiment includes: a non-contact distance measurement device 61 that measures a distance between a light entering surface of the infrared-light receiving unit 16 and a first surface (e.g., an upper surface) of the wafer 20; a transmission path 62 for transmitting distance information (sensing data) measured by the non-contact distance measurement device 61 to the temperature measuring device 10, in adding to providing the temperature measuring device 10, the prober 50, and the test head 13 as in the first embodiment.

Moreover, the temperature measuring device 10 according to the second embodiment includes a temperature conversion unit 101, a temperature correction unit 102, and a temperature display unit 103.

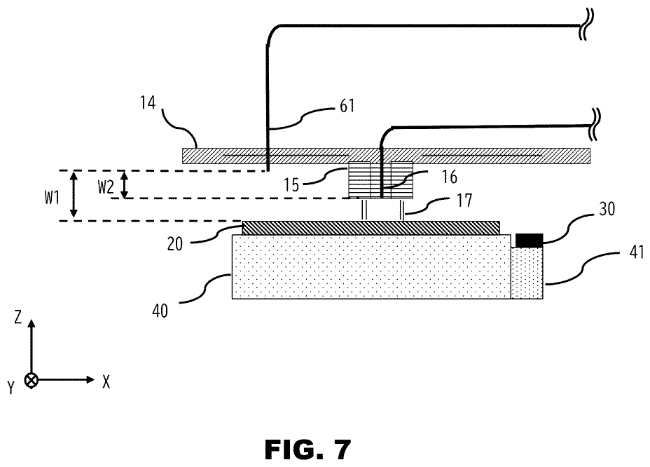

FIG. 7 is an explanatory diagram for describing a distance measurement performed by the length measuring device 61 according to the second embodiment.

The non-contact distance measurement device 61 measures a distance to an object in a non-contact manner by transmitting light toward the object and receiving the reflected light from the object.

For example, as illustrated in FIG. 7, a light entrance portion (end portion) of the infrared-light receiving unit 16 is provided facing the semiconductor device on the wafer 20, and a position of the light entrance portion of the infrared-light receiving unit 16 is a reference in the measurement of the amount of infrared radiation.

The position of the light entrance portion (end portion) of the infrared-light receiving unit 16 and the position of the end portion of the non-contact distance measurement device 61 are assumed to be known in advance, and a distance (a distance in a Z-axial direction; i.e., the height) between the end portion of the non-contact distance measurement device 61 and the light entrance portion of the infrared-light receiving unit 16 is “W2”.

When the non-contact distance measurement device 61 targets an upper surface of the wafer 20, a distance (distance in the Z-axial direction; i.e., the height) between the end portion of the non-contact distance measurement device 61 and the upper surface of the wafer 20 is “W1”.

### (B-2) Operation of Second Embodiment

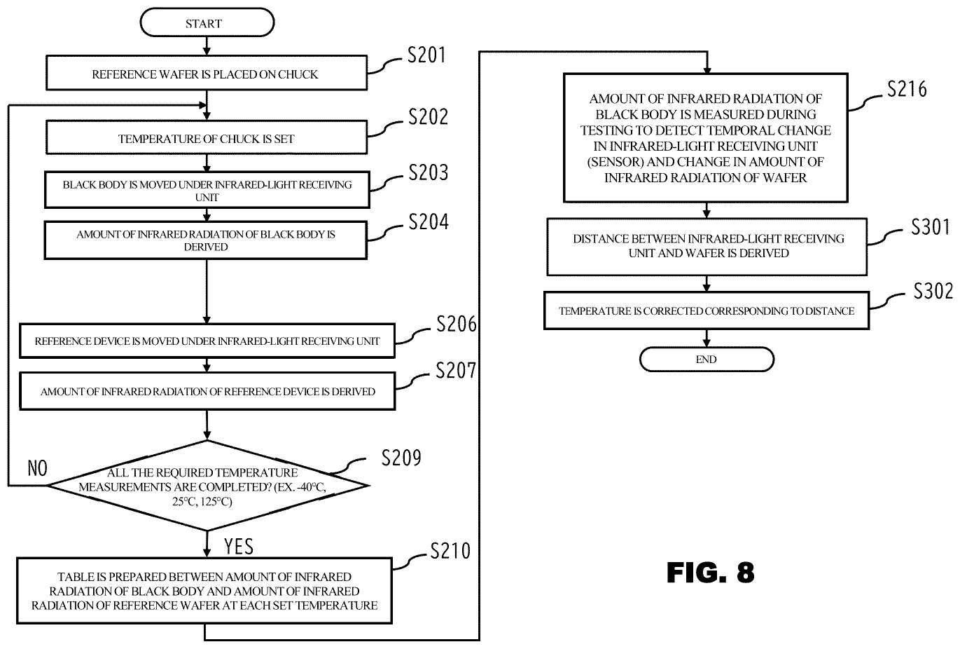

FIG. 8 is a flow chart illustrating an operation of a calibration process of the temperature measuring device 10 in the inspection apparatus 1A according to the second embodiment.

The processes in S201 to S204, S206, S207, S209, S210, and S216 in FIG. 8 are the same as those described in FIG. 4 of the first embodiment. Since these processes have already been described in the first embodiment, these processes will be referred to the description in FIG. 4 of the first embodiment. Processes in S301 to S302 will be described here.

### [Step S301]

Distance data from the non-contact distance measurement device 61 is transmitted to the temperature correction unit 102 in the temperature measuring device 10 (Step S301).

An example of a derivation method of the distance between the non-contact distance measurement device 61 and the upper surface of the wafer 20 will now be described here.

For example, the distance (distance in the Z-axial direction; i.e., the height) W2 between the end portion of the non-contact distance measurement device 61 and the light entrance portion of the infrared-light receiving unit 16 is set in advance. Accordingly, a distance “W1-W2” between the light entrance portion (end portion) of the infrared-light receiving unit 16 and the upper surface of the wafer 20 is derived by subtracting the distance W2 from the distance W1 to the wafer 20 measured by the non-contact distance measurement device 61.

### [Step S302]

The temperature correction unit 102 obtains a corrected temperature corresponding to the distance (W1-W2) between the light entrance portion (end portion) of the infrared-light receiving unit 16 and the upper surface of the wafer 20 with reference to the relationship between the distance to the wafer 20 and the corrected temperature set in advance (Step S302).

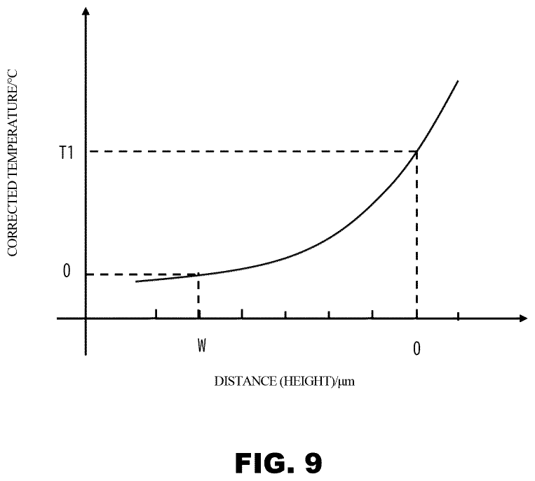

For example, assume that there is a relationship between the distance to the wafer 20 and the corrected temperature as illustrated in FIG. 9. The temperature correction unit 102 obtains a corrected temperature corresponding to the distance (W1-W2) between the light entrance portion (end portion) of the infrared-light receiving unit 16 and the upper surface of the wafer 20 with reference to the relational expression illustrated in FIG. 9. Then, a corrected wafer surface temperature can be obtained by applying the corrected temperature to the actual measured surface temperature of the wafer 20.

### (B-3) Advantageous Effects of Second Embodiment

As described above, according to the second embodiment, the same advantageous effects as those of the first embodiment can be acquired.

Furthermore, the amount of infrared light entering the infrared-light receiving unit may vary in accordance with the distance between the light entrance portion (end) of the infrared-light receiving unit and the upper surface of the wafer, but according to the second embodiment, the surface temperature of the wafer can be corrected by taking into account the correction value corresponding to the distance. As a result, it is possible to provide a more accurate wafer surface temperature.

### (C) Other Embodiments

According to the first and second embodiments described above, the following functions can be realized.

(C-1) When the inspection apparatus is shipped and/or regular calibration is performed, corrections can be performed at any time on the basis of correction values obtained from data of the non-contact thermometer using a calibration blackbody furnace. However, a transmittance may change due to a fitting state, deterioration, or the like of the optical paths (a fiber, a body tube, a lens, etc.).

In contrast, according to the present embodiments, inspection and secondary correction are required using a reference light-emitting body (i.e., a black body+constant temperature) in the actual usage environment, and it is possible to have the function of performing secondary calibration by providing a black body on a portion of the top surface of the wafer chuck, or by providing a wafer chuck with a separate black body, so that the difference in the amount of light emitted between each of these temperature zones is equal to or below a certain level.

(C-2) It is possible to realize a function of measuring a difference between a value detected by a temperature sensor built into the wafer chuck and a measured chuck surface temperature when a wafer with the most average finish among the devices to be measured or a wafer used as the initial reference is heated using the wafer chuck, etc., and correcting measurement errors that vary depending on the design of the actual workpiece, etc.
(C-3) It is possible to realize a function of collecting in advance data on temperature changes due to a distance between an object to be temperature-measured and the infrared-light receiving unit, monitoring this distance information at any time, and adjusting the amount of correction based on the obtained distance information. It is to be noted that the distance information required for this correction may be obtained from a device that performs positioning of the distance in the Z-axis direction or may be obtained from a height sensor provided around the infrared-light receiving unit.

### REFERENCE SIGNS LIST

1 and 1A: Inspection apparatus,
10: Temperature measuring device,
12: Optical fiber,
13: Test head,
14: Probe card,
15: Probe assembly,
16: Infrared-light receiving unit,
17: Probe,
18: Electrical connection unit,
20: Device under test,
30: Black-body,
40: Chuck,
41: Blackbody placement unit,
42: Peripheral edge,
50: Prober,
51: θ-axis stage,
52: Z-axis stage,
53: Y-axis stage,
54: X-axis stage,
61: Non-contact distance measurement device,
62: Signal transmission path,
101: Temperature conversion unit,
102: Temperature correction unit, and
103: Temperature display unit.

1. An inspection apparatus configured to test a device under test by contacting an electrode terminal of the device under test with a conductive contact to electrically connect between a tester and the device under test, the inspection apparatus comprising:
a device-under-test support unit configured to support the device under test;
an infrared-light receiving unit configured to receive infrared rays radiated from the device under test, at least the device under test being as an object to be temperature-measured; and
a temperature measuring device having a temperature conversion function of converting the infrared rays from the infrared-light receiving unit into a temperature of the object to be temperature-measured, wherein
the device-under-test support unit has a black body at a peripheral edge region or in a vicinity of the peripheral edge of the device-under-test support unit.

2. The inspection apparatus according to claim 1, wherein
the temperature measuring device includes
a temperature correction unit configured to acquire an amount of infrared radiation from the black body from the infrared-light receiving unit using the black body arranged at the peripheral edge region or in the vicinity of the peripheral edge of the device-under-test support unit as the object to be temperature-measured, and to correct the temperature converted on the basis of the amount of infrared radiation from the black body.

3. The inspection apparatus according to claim 1, further comprising
a distance measuring unit configured to measure a distance between the device under test supported by the device-under-test support unit and the infrared-light receiving unit, wherein
the temperature correction unit performs temperature correction corresponding to the distance between the device under test and the infrared-light receiving unit with reference to a relationship between the distance between the device under test and the infrared-light receiving unit and the temperature, which are set in advance.
